(19) United States
(12) Patent Application Publication
(10) Pub. No.: US 2017/0156237 A1
(43) Pub. Date: Jun. 1, 2017

(54) MOUNTING APPARATUS FOR FAN

(71) Applicant: HON HAI PRECISION INDUSTRY CO., LTD., New Taipei (TW)

(72) Inventors: KUAN-CHIN YU, New Taipei (TW); TUNG-HO SHIH, New Taipei (TW)

(21) Appl. No.: 14/974,478

(22) Filed: Dec. 18, 2015

(30) Foreign Application Priority Data
Nov. 27, 2015 (CN) 201510840118.X

(51) Int. Cl. H05K 7/20

(52) U.S. Cl. CPC H05K 7/20172

(57) ABSTRACT

A mounting apparatus is used to fasten a fan. The mounting apparatus includes a mounting plate and a fastening bracket. The fastening bracket includes a fastening panel and a fastening member. The fastening member includes a first fastening portion and a second fastening portion. The first fastening portion is slidably mounted on the fastening panel. The second fastening portion is fastened to the fastening panel. The mounting plate defines a first slot and a second slot. The first fastening portion is slidably received in the first slot to prevent the fastening bracket from moving relative to the mounting plate along a first direction. The second fastening portion is received in the second slot to prevent the fastening bracket from moving relative to the mounting plate along a second direction. The second direction is substantially perpendicular to the first direction.

### CROSS-REFERENCE TO RELATED APPLICATIONS

This application claims priority to Chinese Patent Application 201510840118.X filed on Nov. 27, 2015, the contents of which are incorporated by reference herein.

### FIELD

The subject matter herein generally relates to a mounting apparatus for a fan.

### BACKGROUND

When electronic devices are operating, microprocessors can generate heat. If the heat is not dissipated in time, the electronic devices can be damaged.

### BRIEF DESCRIPTION OF THE DRAWINGS

Implementations of the present technology will now be described, by way of example only, with reference to the attached figures.

FIG. 1 is an exploded, isometric view of one embodiment of a mounting apparatus.

FIG. 2 is similar to FIG. 1, but viewed from a different angle.

FIG. 3 is an enlarged view of a circled portion III of FIG. 2.

FIG. 4 is an assembled, isometric view of the mounting apparatus of FIG. 1.

FIG. 5 is similar to FIG. 1, but viewed from a different angle.

### DETAILED DESCRIPTION

It will be appreciated that for simplicity and clarity of illustration, where appropriate, reference numerals have been repeated among the different figures to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising” when utilized, means “including, but not necessarily limited to”; it specifically indicates open-ended inclusion or membership in the so-described combination, group, series and the like.

The present disclosure is described in relation to a mounting apparatus. In at least one embodiment, the mounting apparatus is used to mount a fan. The mounting apparatus includes a mounting plate and a fastening bracket. The fastening bracket includes a fastening panel and a fastening member. The fastening member includes a first fastening portion and a second fastening portion. The first fastening portion is slidably mounted on the fastening panel. The second fastening portion is fixed to the fastening panel. The mounting plate defines a first slot and a second slot. The first fastening portion is slidably received in the first slot to prevent the fastening bracket from moving relative to the mounting plate along a first direction. The second fastening portion is received in the second slot to prevent the fastening bracket from moving relative to the mounting plate along a second direction. The second direction is substantially perpendicular to the first direction.

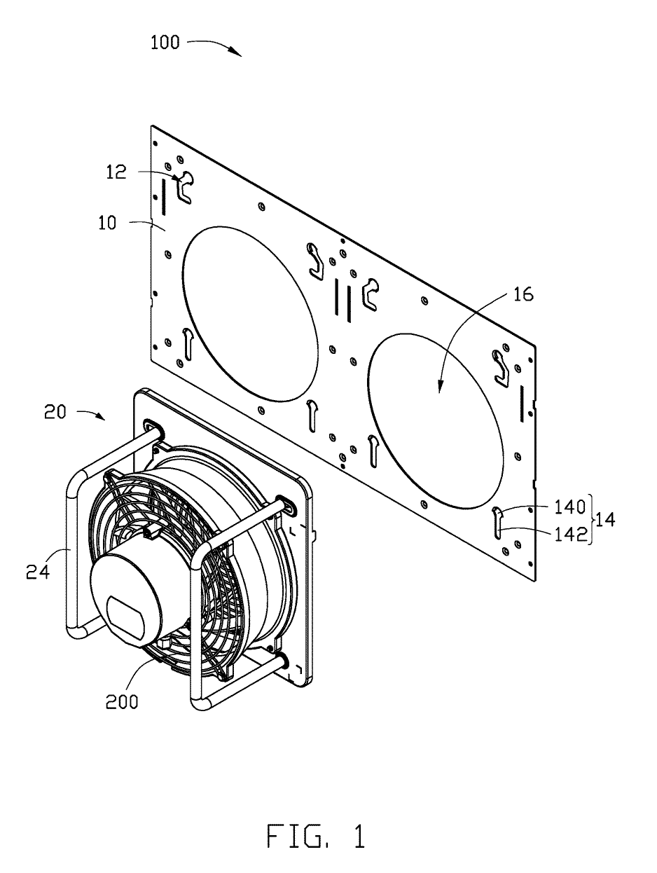

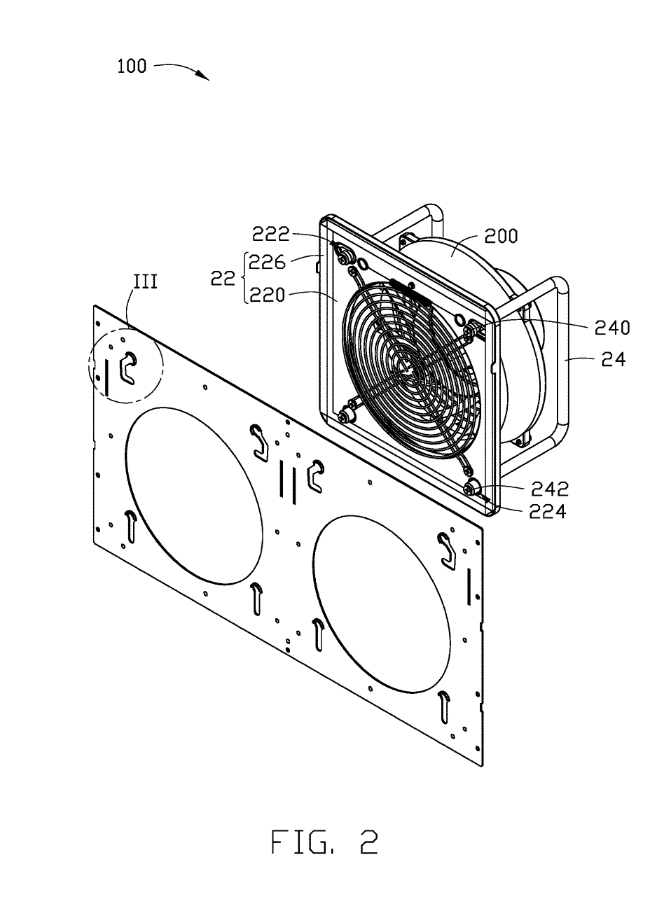

FIGS. 1-2 illustrate one embodiment of a mounting apparatus 100. The mounting apparatus 100 includes a mounting plate 10 and a fastening bracket 20. In at least one embodiment, the mounting apparatus 100 is used to mount a fan 200.

The mounting plate 10 defines two first slots 12, two second slots 14, and a vent 16. In at least one embodiment, the vent 16 can be substantially circular.

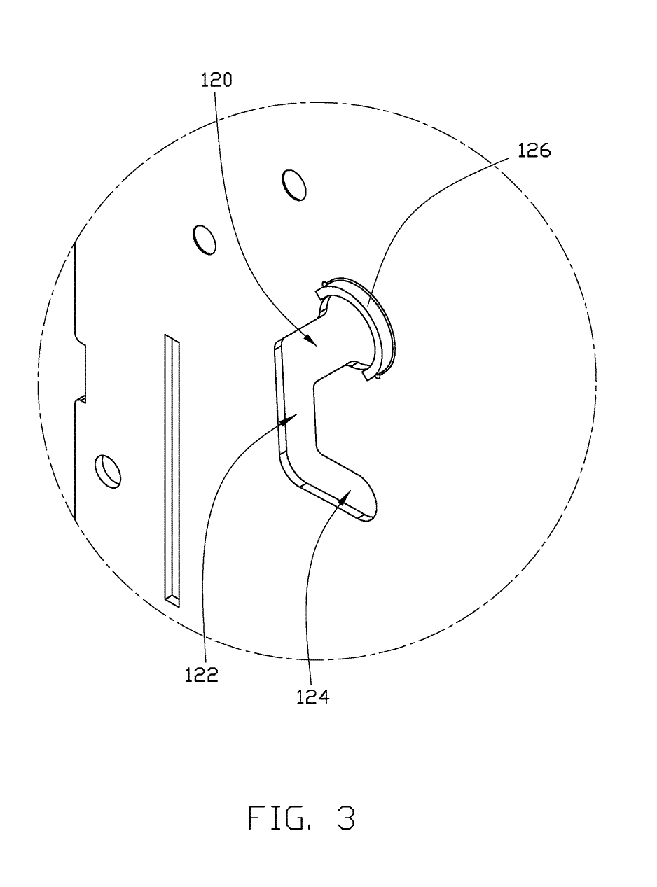

FIG. 3 illustrates one embodiment of a first slot 12. The first slot 12 defines a first guiding portion 120, an extension portion 122, and a stop portion 124. The first guiding portion 120 communicates with the extension portion 122. The extension portion 122 communicates with the stop portion 124. An acute angle is formed by an extending direction of the first guiding portion 120 and an extending direction of the extension portion 122. The extending direction of the extension portion 122 can be substantially perpendicular to an extending direction of the stop portion 124. Each first slot 12 includes a flange 126. The flange 126 extends from an edge of the first guiding portion 120.

FIG. 1 illustrates one embodiment of the second slots 14. Each second slot 14 defines a second guiding portion 140 and a locking portion 142. An extending direction of the locking portion 142 can be substantially perpendicular to the extending direction of the stop portion 124. In at least one embodiment, the second guiding portion 140 can be substantially circular. A diameter of the second guiding portion 140 is greater than a width of the locking portion 142.

FIG. 1 illustrates one embodiment of the fastening bracket 20. The fastening bracket 20 includes a fastening panel 22 and two fastening members 24. The fastening panel 22 includes a body 220 and a shock-absorption frame 226. The body 220 is fixed to the shock-absorption frame 226. The body 220 defines two grooves 222 and two through holes 224. An extending direction of each groove 222 can be substantially parallel to the extending direction of the stop portion 124. Each through hole 224 can be substantially circular. Each fastening member 24 includes a first fastening portion 240 and a second fastening portion 242. Each fastening member 24 can be substantially U-shaped. The first fastening portion 240 and the second fastening portion 242 are two ends of the fastening member 24. The shock-absorption frame 226 can be made of elastic material.

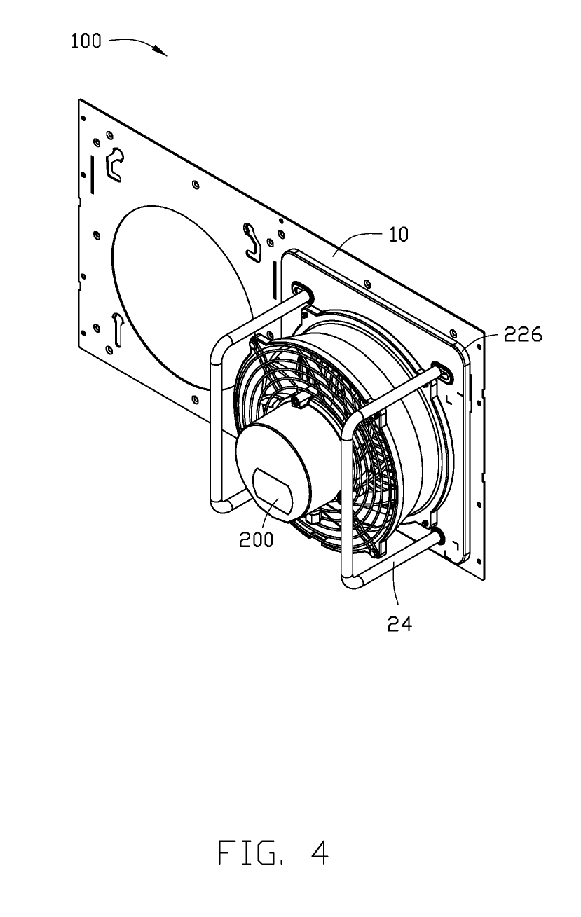

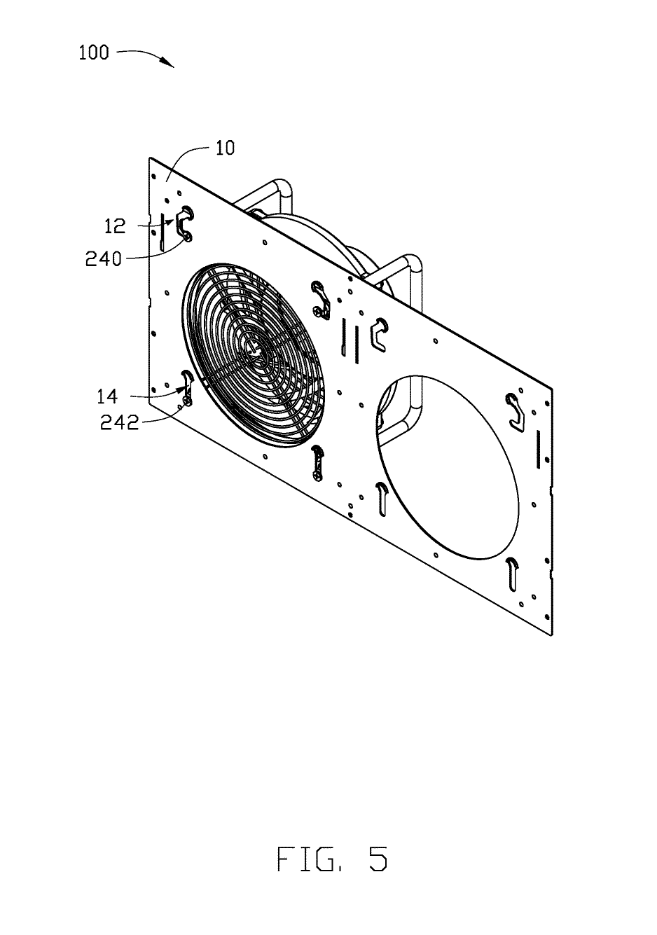

FIGS. 4-5 illustrate the mounting apparatus 100 being assembled. The fan 200 is fixed to the fastening panel 22 via a plurality of screws (not shown). The first fastening portion 240 of each fastening member 24 is received in one of the two grooves 222 and can be moved along the groove 222. The second fastening portion 242 of each fastening member 24 is received in one of the two through holes 224. The shock-absorption frame 226 abuts the mounting plate 10. The first fastening portion 240 extends into the first guiding portion 120 via the flange 126. The second fastening portion 242 extends into the second guiding portion 140. The first fastening portion 240 is moved through the first guiding portion 120 and the extension portion 122, and is engaged in the stop portion 124. The first fastening portion 240 abuts an end of the stop portion 124 to prevent the fastening bracket 20 from moving relative to the mounting plate 10 along a first direction. The first direction can be substantially perpendicular to the extending direction of the stop portion 124. The first fastening portion 240 is moved along the groove 222. The second fastening portion 242 is moved along the locking portion 142. The second fastening portion 242 abuts an end of the locking portion 142 to prevent the fastening bracket 20 from moving relative to the mounting plate 10 along a second direction. The second direction can be substantially perpendicular to the first direction.

When the fastening bracket 20 needs to be moved away from the mounting plate 10, the fastening bracket 20 is moved along the first direction. The first fastening portion 240 moves out of the first slot 12. The second fastening portion 242 moves out of the second slot 14.

The embodiments shown and described above are only examples. Many details are often found in the art such as the other features of the mounting apparatus. Therefore, many such details are neither shown nor described. Even though numerous characteristics and advantages of the present technology have been set forth in the foregoing description, together with details of the structure and function of the present disclosure, the disclosure is illustrative only, and changes may be made in the details, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A mounting apparatus for a fan comprising:
a mounting plate defining a first slot and a second slot; and
a fastening bracket comprising:
a fastening panel and a fastening member comprising:
a first fastening portion slidably received in the first slot to prevent the fastening bracket moving relative to the mounting plate along a first direction; and
a second fastening portion being slidably mounted on the fastening panel being fixed to the fastening panel and is received in the second slot to prevent the fastening bracket moving relative to the mounting plate along a second direction, and the second direction is substantially perpendicular to the first direction.

2. The mounting apparatus of claim 1, wherein the fastening member is substantially U-shaped, and the first fastening portion and the second fastening portion are located on opposite ends of the fastening member.

3. The mounting apparatus of claim 1, wherein the fastening bracket defines a groove and a through hole, the first fastening portion extends into the groove and is moveable within the groove, and the second fastening portion is received in the through hole.

4. The mounting apparatus of claim 1, wherein the first slot defines a first guiding portion, an extension portion, and a stop portion, the extension portion communicates with the stop portion and the first guiding portion, and an acute angle is defined by an extending direction of the first guiding portion and an extending direction of the extension portion.

5. The mounting apparatus of claim 4, wherein the extending direction of the extension portion is substantially perpendicular to an extending direction of the stop portion.

6. The mounting apparatus of claim 5, wherein the fastening panel defines a groove, and an extending direction of the groove is substantially parallel to the extending direction of the stop portion.

7. The mounting apparatus of claim 5, wherein the second slot defines a second guiding portion and a locking portion, the second guiding portion is substantially circular, and a diameter of the second guiding portion is greater than a width of the locking portion.

8. The mounting apparatus of claim 7, wherein an extending direction of the locking portion is substantially perpendicular to the extending direction of the stop portion.

9. The mounting apparatus of claim 1, wherein the fastening panel includes a shock-absorption frame, and when the fastening bracket is fixed to the mounting plate, the shock-absorption frame abuts the mounting plate.

10. A mounting apparatus comprising:
a mounting plate defining a first slot, the first slot defining a first guiding portion, an extension portion, and a stop portion, the extension portion communicating with the stop portion and the first guiding portion, and an acute angle being defined by an extending direction of the first guiding portion and an extending direction of the extension portion; and
a fastening bracket comprising a fastening panel and a fastening member, the fastening member comprising a first fastening portion, and the first fastening portion being engaged with the fastening panel;
wherein the first fastening portion is movable through the first guiding portion and the extension portion to be engaged in the stop portion, and the fastening bracket to the mounting plate.

11. The mounting apparatus of claim 10, wherein the fastening member further comprises a second fastening portion, the fastening member is substantially U-shaped, and the first fastening portion and the second fastening portion are located on opposite ends of the fastening member.

12. The mounting apparatus of claim 11, wherein the fastening bracket defines a groove and a through hole, the first fastening portion is configured to extend into the groove and move within the groove, and the second fastening portion is received in the through hole.

13. The mounting apparatus of claim 11, wherein the mounting plate further defines a second slot, the second fastening portion is received in the second slot to fix the fastening bracket to the mounting plate.

14. The mounting apparatus of claim 13, wherein the second slot defines a second guiding portion and a locking portion, the second guiding portion is substantially circular, and a diameter of the second guiding portion is greater than a width of the locking portion.

15. The mounting apparatus of claim 14, wherein an extending direction of the locking portion is substantially perpendicular to the extending direction of the stop portion.

16. The mounting apparatus of claim 10, wherein the extending direction of the extension portion is substantially perpendicular to an extending direction of the stop portion.

17. The mounting apparatus of claim 10, wherein the fastening panel defines a groove, and an extending direction of the groove is substantially parallel to the extending direction of the stop portion.

18. The mounting apparatus of claim 10, wherein the fastening panel includes a shock-absorption frame, and when the fastening bracket is fixed to the mounting plate, the shock-absorption frame abuts the mounting plate.
